(19) United States
(12) Patent Application Publication
(10) Pub. No.: US 2009/0040802 A1
(43) Pub. Date: Feb. 12, 2009

(54) SEMICONDUCTOR MEMORY DEVICE, MEMORY-MOUNTED LSI AND FABRICATION METHOD FOR SEMICONDUCTOR MEMORY DEVICE

(75) Inventor: Ken Arakawa, Shiga (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INDUSTRIAL CO. LTD

(21) Appl. No.: 12/176,633

(22) Filed: Jul. 21, 2008

(30) Foreign Application Priority Data
Aug. 7, 2007 (JP) 2007-205053

(51) Int. Cl. G11C 5/02; G11C 11/00; H01L 21/00

(52) U.S. Cl. 365/51; 365/158; 365/148; 438/128; 257/E21.001

(57) ABSTRACT

The semiconductor memory device includes a memory cell array block having one or more stages of memory cell arrays stacked one on another, each memory cell array including a plurality of memory cells placed in a matrix at respective intersections of a plurality of word lines and a plurality of bit lines. A plurality of MOS transistor blocks are provided which are same in the configuration of circuit elements and include MOS transistors as one kind of the circuit elements. In part of the plurality MOS transistor blocks, the MOS transistors are used for drive of the word lines or the bit lines, while in at least part of the remaining MOS transistor blocks, the MOS transistors are used as MOS capacitors.

### BACKGROUND OF THE INVENTION

1. Field of the Invention

The present invention relates to a semiconductor memory device having cross-point memory cells, a memory-mounted LSI including such a semiconductor memory device and a circuit operating in response to data stored in the semiconductor memory device, and a fabrication method for such a semiconductor memory device.

2. Description of the Prior Art

In audio equipment and the like, for example, an LSI including a memory as well as a central processing unit (CPU) and a digital signal processor (DSP) (hereinafter, such an LSI is called a memory-mounted LSI) is often used. In such a memory-mounted LSI, code for an application and the like used by the CPU and the DSP are stored in the mounted memory.

In such a memory-mounted LSI, it is sometimes attempted to change its function or reduce application code to hence replace the LSI with a less expensive LSI product smaller in memory capacity. In some cases, therefore, such a memory-mounted LSI is expanded to a variety of product types different in memory capacity, and such product types are brought to market.

As an example of the memory-mounted LSI expanded to various product types different in memory capacity, there exists a one-chip microcomputer that changes the memory capacity by changing the length of only one side of a memory block while setting the other side thereof at the length of the area on the chip on which the device is placed (see Japanese Patent Gazette No. 2624394 and U.S. Pat. No. 4,447,881, for example).

However, when it is attempted to expand a semiconductor memory device and a memory-mounted LSI to a variety of product types different in memory capacity, a photomask must be designed for each memory capacity, and this blocks enhancement in development efficiency. To address this problem, it is considered to design/develop a photomask common to various memory capacities in which circuits such as drivers are arranged to fit to the memory having the maximum capacity. In this case, however, the chip size of a product type small in memory capacity will be made to fit to the product type maximum in capacity, and this may possibly increase the chip unit price. In other words, the merit brought by the design efficiency may possibly be surpassed by the demerit of raising the chip unit price due to the sharing of the photomask. In particular, this demerit is considered more eminent in an LSI having memory as well as CPU and the like.

In a semiconductor memory device and a memory-mounted LSI, also, characteristics such as the AC characteristic, the EMC resistance and the latch-up resistance are different with the difference in memory capacity in some cases. In such cases, boards on which the semiconductor memory device and the memory-mounted LSI are mounted will be designed according to the characteristics of the respective product types.

### SUMMARY OF THE INVENTION

An object of the present invention is providing a semiconductor memory device and a memory-mounted LSI that can be easily expanded to a variety of product types different in memory capacity with uniform characteristics being secured over the product types while preventing increase in chip unit price with increase in chip area.

To attain the above object, the semiconductor memory device of the present invention includes:

a memory cell array block having one or more stages of memory cell arrays stacked one on another, each memory cell array including a plurality of memory cells placed in a matrix at respective intersections of a plurality of word lines and a plurality of bit lines; and

a plurality of MOS transistor blocks same in the configuration of circuit elements, MOS transistors being included as one kind of the circuit elements,

wherein in part of the plurality of MOS transistor blocks, the MOS transistors are used for drive of the plurality of word lines or the plurality of bit lines, and in at least part of the remaining MOS transistor blocks, the MOS transistors are used as MOS capacitors.

The fabrication method of the present invention is a fabrication method for a semiconductor memory device including a memory cell array block having one or more stages of memory cell arrays stacked one on another, each memory cell array including a plurality of memory cells placed in a matrix at respective intersections of a plurality of word lines and a plurality of bit lines, the semiconductor memory device being expanded to product types different in capacity depending on the number of stages of memory cell arrays, the method including:

a lower layer formation step of forming a plurality of MOS transistor blocks same in the configuration of circuit elements and including MOS transistors as one kind of the circuit elements in a lower layer;

a wiring layer formation step of executing a first sub-step of wiring the terminals of each of the MOS transistors in a wiring layer so that all of the plurality of MOS transistor blocks drive the plurality of word lines or the plurality of bit lines in fabrication of a product type maximum in capacity among the product types, and executing a second sub-step of wiring the terminals of each of the MOS transistors in the wiring layer so that the MOS transistors drive the plurality of word lines or the plurality of bit lines in part of the plurality of MOS transistor blocks and wiring the terminals of each of the MOS transistors in the wiring layer so that the MOS transistors function as MOS capacitors in at least part of the remaining MOS transistor blocks in fabrication of a product type other than the product type maximum in capacity among the product types; and

a memory cell array addition step of, in the case of requiring an additional memory cell array, stacking a desired number of additional wiring layers including the memory cell array on the wiring layer.

Alternatively, the semiconductor memory device of the present invention includes a memory cell array block having one or more stages of memory cell arrays stacked one on another, each memory cell array including a plurality of memory cells placed in a matrix at respective intersections of a plurality of word lines and a plurality of bit lines, the semiconductor memory device being expanded to product types different in capacity depending on the number of stages of memory cell arrays,

wherein the semiconductor memory device further includes a plurality of MOS transistor blocks same in the configuration of circuit elements and including MOS transistors as one kind of the circuit elements,

for a product type maximum in capacity among the product types, all of the plurality of MOS transistor blocks are used for drive of the plurality of word lines or the plurality of bit lines, and

for a product type other than the product type maximum in capacity among the product types, the MOS transistors are used for drive of the plurality of word lines or the plurality of bit lines in part of the plurality of MOS transistor blocks while the MOS transistors are used as MOS capacitors in at least part of the remaining MOS transistor blocks.

Accordingly, in expansion of memory to a variety of capacity types, MOS capacitors having a capacitance corresponding to the memory capacity of each type are formed.

### BRIEF DESCRIPTION OF THE DRAWINGS

FIG. 1 is a plan view of the entire configuration of a semiconductor memory device 100 of Embodiment 1.

FIG. 2 is a cross-sectional view of the semiconductor memory device 100 taken along a word line WLa1.

FIG. 3 is a cross-sectional view of the semiconductor memory device 100 taken along a bit line BLa1.

FIG. 4 is a cross-sectional view of a semiconductor memory device 200 of Embodiment 2 taken along a word line WLa1.

FIG. 5 is a cross-sectional view of the semiconductor memory device 200 taken along a bit line BLa1.

FIG. 6 is a plan view of the entire configuration of a memory-mounted LSI 300 of Embodiment 3.

FIG. 7 is a cross-sectional view of the memory-mounted LSI 300 taken along a word line WLa1.

FIG. 8 is a cross-sectional view of the memory-mounted LSI 300 taken along a bit line BLa1.

FIG. 9 is a cross-sectional view of the memory-mounted LSI 300 taken along the word line WLa1 in a small capacity product type having one stage of memory cell array 120.

FIG. 10 is a cross-sectional view of the memory-mounted LSI 300 taken along the bit line BLa1 in the small capacity product type having one stage of memory cell array 120.

FIG. 11 is a view illustrating a fabrication method for a semiconductor memory device of an embodiment of the present invention.

FIG. 12 is a block diagram of an audio apparatus 500 incorporating the memory-mounted LSI 300.

FIG. 13 is a general view of an automobile equipped with the audio equipment 500.

### DESCRIPTION OF THE PREFERRED EMBODIMENTS

Hereinafter, preferred embodiments of the present invention will be described with reference to the accompanying drawings. Note that in the following description on the embodiments and alterations, components having the same functions are denoted by the same reference numerals, and description of such components is not repeated.

### Embodiment 1

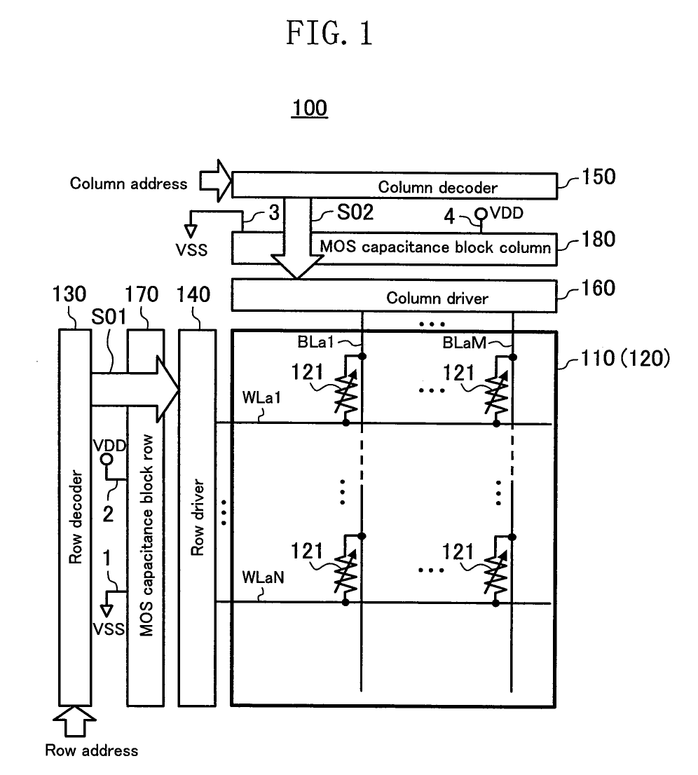

FIG. 1 is a plan view of the entire configuration of a semiconductor memory device 100 of Embodiment 1 of the present invention. One memory macro of a type greatest in memory capacity as a product (hereinafter, such a product type is called a maximum capacity product type) is designed/developed, and the memory macro is expanded to product types smaller in capacity than the maximum capacity product type (hereinafter, such product types are called small capacity product types). The semiconductor memory device 100 is one of such small capacity product types. The memory macro is provided with row drivers and column drivers of the numbers necessary for the maximum capacity product type.

(Configuration of Semiconductor Memory Device 100)

As shown in FIG. 1, the semiconductor memory device 100 includes a memory cell array block 110, a row decoder 130, a row driver 140, a column decoder 150, a column driver 160, a MOS capacitance block row 170 and a MOS capacitance block column 180.

The memory cell array block 110 includes one stage of memory cell array 120 or a plurality of stages of memory cell arrays 120 stacked one on another. In this embodiment, an example of one-stage memory cell array 120 will be described.

The memory cell array 120 includes N (N is a natural number) word lines (WLa1, . . . , WLaN), M (M is a natural number) bit lines (BLa1, . . . , BLaM), and a plurality of cross-point memory cells 121. In FIG. 1, the memory cells 121 are respectively represented by a symbol of variable resistance.

Examples of cross-point memory cells include a magnetic random access memory (MRAM) using ferromagnetic tunneling magneto-resistance (TMR) and a resistive random access memory (ReRAM) using field-based colossal electro-resistance (CER). As another example, there is also a memory using a diode antifuse as a one-time programmable (OTP) memory element. The memory using a diode antifuse is based on the principle that data is stored by short-circuiting the oxide of a memory cell at high voltage.

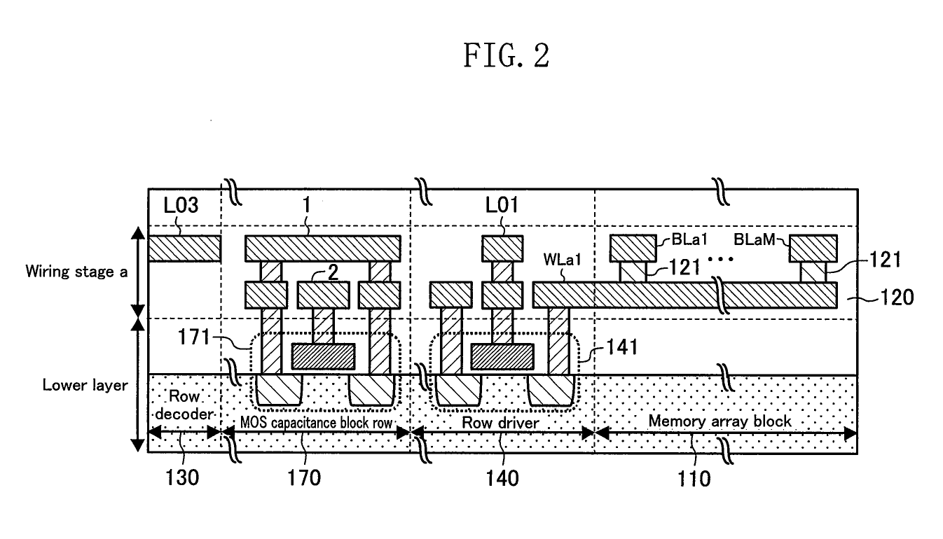

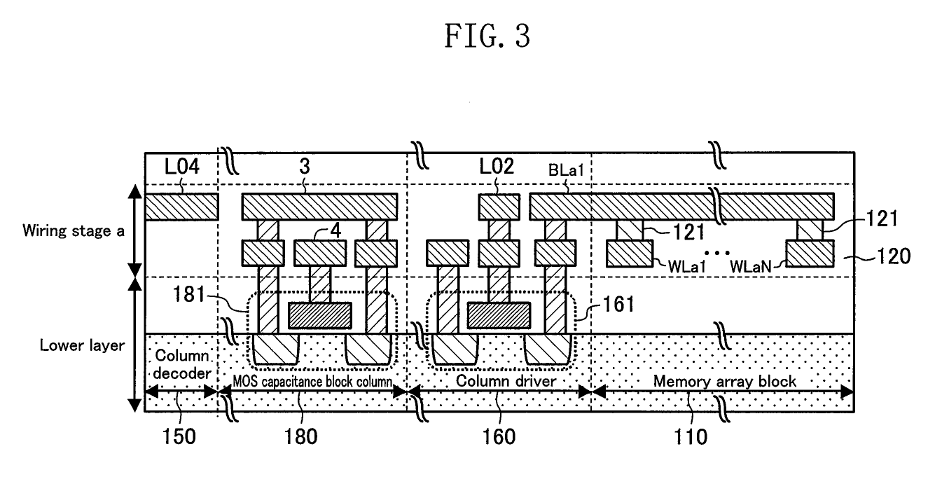

FIG. 2 is a cross-sectional view of the semiconductor memory device 100 taken along the word line WLa1. FIG. 3 is a cross-sectional view of the semiconductor memory device 100 taken along the bit line BLa1.

Referring to FIGS. 2 and 3, a wiring stage a is composed of two wiring layers, and the memory cell array 120 is formed over the two wiring layers. To state more specifically, the word lines WLa1, . . . , WLaN are placed in one of the two wiring layers while the bit lines BLa1, . . . , BLaM are placed in the other wiring layer, with the memory cells 121 being placed in a matrix at the respective intersections of these word lines and bit lines. If N=2048 and M=2048, the capacity of the memory cell array 120 is 4 Mbits from the number of memory cells formed at the intersections.

Also as shown in FIGS. 2 and 3, the circuit elements of the peripheral circuits such as the row decoder 130, the row driver 140, the column decoder 150, the column driver 160, the MOS capacitance block row 170 and the MOS capacitance block column 180 are formed in a lower layer.

The row decoder 130 decodes a row address to generate a row driver activating signal S01 indicating a word line (any of the word lines WLa1, . . . , WLaN) to be selected.

The row driver 140, for driving any word line corresponding to the row driver activating signal S01, includes a MOS transistor 141 as shown in FIG. 2. The MOS transistor 141 receives the row driver activating signal S01 at its gate via a row driver activating signal line L01 (see FIG. 2) and drives a word line corresponding to the row driver activating signal S01.

The column decoder 150 decodes a column address to generate a column driver activating signal S02 indicating a bit line (any of the bit lines BLa1, . . . , BLaM) to be selected.

The column driver 160, for driving any bit line corresponding to the column driver activating signal S02, includes a MOS transistor 161 as shown in FIG. 3. The MOS transistor 161 receives the column driver activating signal S02 at its gate via a column driver activating signal line L02 (see FIG. 3) and drives a bit line corresponding to the column driver activating signal S02.

The MOS capacitance block row 170, which is the same as the row driver 140 in the configuration of its circuit elements in the lower layer, has also a MOS transistor 141. In the semiconductor memory device 100, which is a semiconductor memory device obtained by expanding the memory macro developed for the maximum capacity product type, row drivers and column drivers are placed to fit to the number of stages of memory cell arrays 120 in the maximum capacity product type. The MOS capacitance block row 170 is one of such row drivers.

In this embodiment, in which one stage of memory cell array 120 is provided and the row driver 140 corresponds to this memory cell array 120, the MOS capacitance block row 170 does not need to function as the row driver. Instead, it functions as capacitors.

More specifically, in the MOS capacitance block row 170, the MOS transistor 141 functions as a capacitor (MOS capacitor 171), not as a MOS transistor for driving. In more detail, in the MOS capacitance block row 170, the gate of the MOS capacitor 171 is not connected with the row driver activating signal S01, but instead connected with a power supply terminal VDD2 via a wiring layer of the wiring stage a. Also, the source and drain of the MOS capacitor 171 are connected with a power supply terminal VSS1 in a wiring layer of the wiring stage a. In other words, the MOS capacitor 171 is used as the smoothing capacitance for the power supply. Note that as shown in FIG. 2, a row driver activating signal line L03 for supplying a row driver activating signal S03 for a second-layer memory cell array 120 is formed in the wiring stage a although it is not used.

Likewise, the MOS capacitance block column 180, which is the same as the column driver 160 in the configuration of its circuit elements in the lower layer, has also a MOS transistor 161. That is, the MOS capacitance block column 180 is one of column drivers placed to fit to the number of stages of memory cell arrays 120 in the maximum capacity product type.

In the MOS capacitance block column 180, also, the MOS transistor 161 functions as a capacitor (MOS capacitor 181). In more detail, the gate of the MOS capacitor 181 is not connected with the column driver activating signal, but instead connected with a power supply terminal VDD4 via a wiring layer of the wiring stage a. Also, the source and drain of the MOS capacitor 181 are connected with a power supply terminal VSS3 in a wiring layer of the wiring stage a. In other words, the MOS capacitor 181 is used as the smoothing capacitance for the power supply. Note that as shown in FIG. 3, a column driver activating signal line L04 for supplying a column driver activating signal S04 for a second-stage memory cell array 120 is formed in the wiring stage a although it is not used.

Note that the lower portions of the row driver 140, the column driver 160, the MOS capacitance block row 170 and the MOS capacitance block column 180 (i.e., the portions of circuit elements excluding interconnects) are herein called MOS transistor blocks. Note also that the voltages VSS1, VSS3, VDD2 and VDD4 as power supply terminals are assumed to be the same as internal power supplies of the LSI product including the memory peripheral circuits.

In this embodiment, no circuit is especially placed under the memory cell array 120. If a product type larger in the number of stages of memory cell arrays 120 is to be provided, the row driver 140, the column driver 160, the MOS capacitance block row 170, the MOS capacitance block column 180 and the like may be formed using the area under the memory cell array 120.

As described above, in this embodiment, while part of the MOS transistor blocks is used for drive of word lines or bit lines, the remaining part of the MOS transistor blocks unused for the drive is made usable as MOS capacitors, for a small capacity product type.

For example, the MOS capacitance securable when the number of word lines N=2048 and the number of bit lines M=2048 is calculated as follows. Assuming that the relative dielectric constant of the oxide film of MOS transistors=4.2, the thickness of the oxide film=6 nm, the transistor length=0.2 μm and the total transistor width/driver=60 μm, the MOS capacitance value/driver=8.85E−12 [F/m]×4.2/6.0E−9 [m]×0.2E−6 [m]×60×E−6 [m]=about 74 [fF]. Hence, the MOS capacitance value=2×2048×74 [fF]=about 300 [pF].

The effect of the MOS capacitance of about 300 pF on the characteristics will be considered. In small-scale LSI products such as microcomputer products, for example, in which the chip area is not more than 10 mm² in many cases, a total smoothing capacitance of as little as several thousands of pF is secured in some cases. In consideration of this, the value of about 300 pF securable in this embodiment is a significant value as the smoothing capacitance.

For example, consider a semiconductor memory device having three stages of memory cell arrays 120 with a total capacity of 12 Mbits as the maximum capacity product type. In this case, an 8-Mbit semiconductor memory device as its small capacity product type will be able to secure a MOS capacitance value of about 300 pF, and likewise, a 4-Mbit semiconductor memory device will be able to secure a MOS capacitance value of about 600 pF. Such capacitance values are expected to exhibit a very significant effect.

Examples of characteristics expected to be improved by use of the MOS capacitors as the smoothing capacitance for internal power supply include the AC characteristic, the EMC resistance, the latch-up resistance.

As described above, in this embodiment, by designing/developing one memory macro in which peripheral circuits such as row drivers and column drivers are placed to fit to the maximum capacity product type, the memory macro can be used commonly for various product types. This makes the design/development highly efficient, with the expected effect of suppressing the development expense of the memory macro. In other words, the memory macro can be easily expanded to a variety of product types different in memory capacity.

Also, row and column drivers left unused for a small capacity product type due to the adoption of the common memory macro are utilized as capacitors. Hence, characteristics related to the smoothing capacitance can be made uniform among various capacity product types.

Moreover, it is unnecessary to provide a process step of forming gate switches or forming an extra wiring layer under preparation of an extra photomask for producing different product types depending on whether the MOS transistor blocks are used as drivers or as MOS capacitors. In other words, different product types can be easily produced by means of connections of interconnects in the wiring layers for memory cells.

With the adoption of the cross-point memory cells, peripheral circuits can be placed also under the memory cell array. Hence, even with the placement of peripheral circuits to fit to the maximum capacity product type, the increase in chip unit price can be minimized.

All of the drivers unused for drive are not necessarily used as capacitors, but only part of drivers may be used as capacitors. For example, part of the row driver and part of the column driver may be used as capacitors, or only either the row driver or the column driver may be used as capacitors.

The MOS capacitors may otherwise be used as capacitors for determining the circuit constant of an analog circuit.

### Embodiment 2

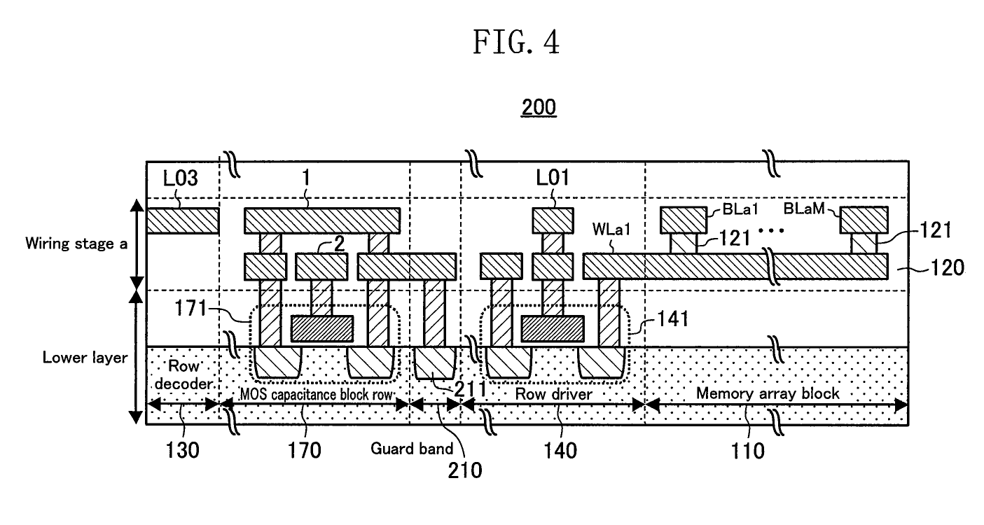

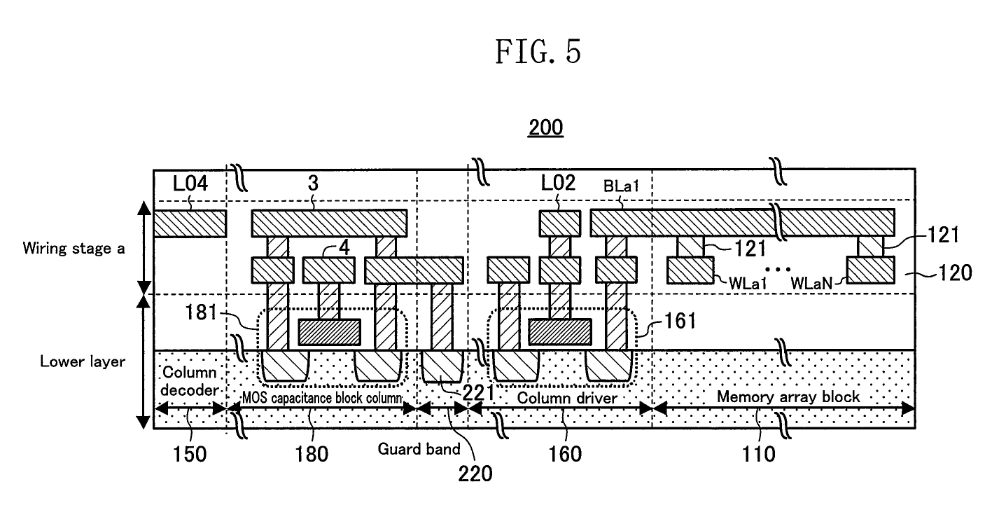

FIG. 4 is a cross-sectional view of a semiconductor memory device 200 taken along the word line WLa1. FIG. 5 is a cross-sectional view of the semiconductor memory device 200 taken along the bit line BLa1.

The semiconductor memory device 200 has a guard band 210 placed between the row driver 140 and the MOS capacitance block row 170 as shown in FIG. 4.

The guard band 210 has a channel stopper 211, which is connected with a channel for the MOS capacitor 171 (VSS1 for the source or drain). With this placement, propagation of noise due to a substrate current from the MOS transistor 141 is suppressed.

Likewise, the semiconductor memory device 200 has a guard band 220 placed between the column driver 160 and the MOS capacitance block column 180 as shown in FIG. 5.

The guard band 220 has a channel stopper 221, which is connected with a channel for the MOS capacitor 181 (VSS3 for the source or drain). With this placement, propagation of noise due to a substrate current from the MOS transistor 161 is suppressed.

As described above, in this embodiment, propagation of noise from the drivers can be suppressed with the presence of the guard bands. Hence, the MOS capacitors can be used as capacitors for analog circuits that should desirably be unaffected by noise.

The channel stoppers 211 and 221 may otherwise be connected with VSS terminals for the MOS transistors in the row driver 140 and the column driver 160, respectively, to suppress propagation of noise from the MOS capacitors to the respective drivers. In other words, the MOS capacitors may be used as the smoothing capacitance for a circuit as the noise source to thereby suppress noise.

Note that although the N-channel MOS transistors were exemplified in this embodiment, guard bands can also be provided for P-channel MOS transistors without causing any problem.

### Embodiment 3

In Embodiment 3, described will be an example of memory-mounted LSI including a semiconductor memory device as well as circuits (CPU and DSP, for example) operating in response to data stored in the semiconductor memory device.

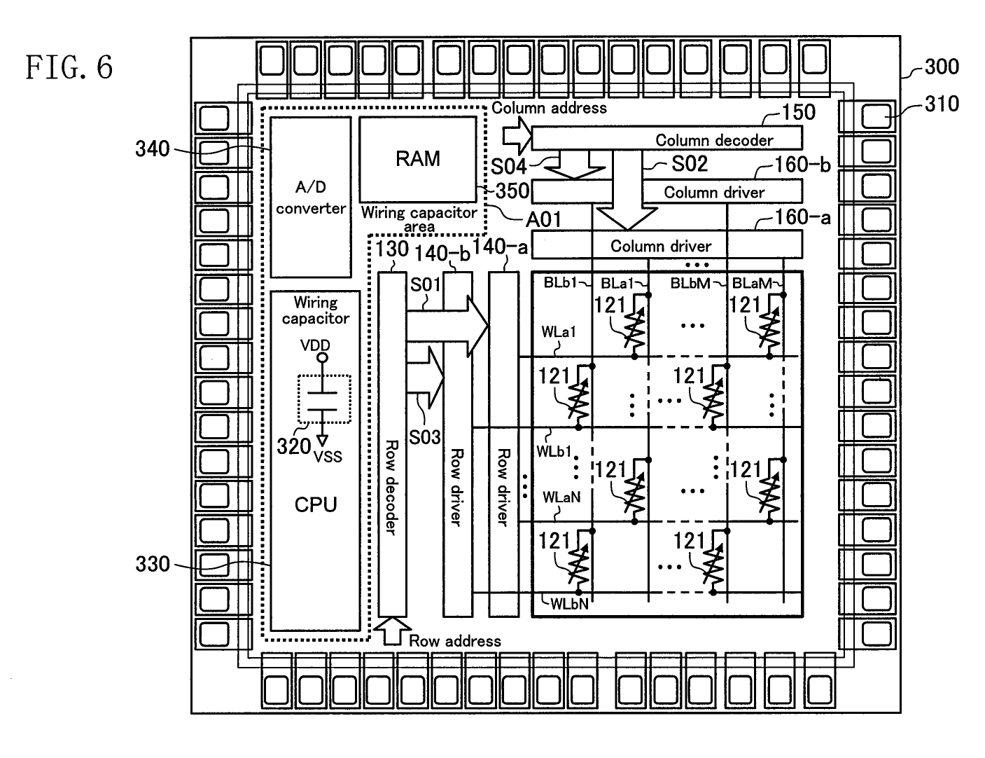

FIG. 6 is a plan view of the entire configuration of a memory-mounted LSI 300 of Embodiment 3 of the present invention. As shown in FIG. 6, the memory-mounted LSI 300 includes the semiconductor memory device 100, external terminals 310, wiring capacitors 320, a CPU 330, an A/D converter 340 and a RAM 350.

In the memory-mounted LSI 300 shown in FIG. 6, the semiconductor memory device 100 has two stages of memory cell arrays 120. The type having two stages of memory cell arrays 120 is the maximum capacity product type in this embodiment, which is expanded to a small capacity product type having one stage of memory cell array 120. In the memory-mounted LSI 300, since the number of memory addresses increases/decreases depending on the product type expanded, not only the memory macro but also a memory macro I/F circuit and memory peripheral circuits are required to have circuit configurations fitting to the memory addresses of the maximum capacity product type. The circuit increase resulted from adopting such circuit configurations is however generally small, and the design thereof is easy.

The memory-mounted LSI 300 as the maximum capacity product type has two row drivers 140 and two column drivers 160. In FIG. 6, to identify the respective row drivers and column drivers, their reference numerals are suffixed with a letter of the alphabet (140-a, 140-b, for example). Those suffixed with a are for the memory cell array in the wiring stage a, and those suffixed with b are for the memory cell array in a wiring stage b (to be described later).

The external terminals 310 are terminals for outputting a signal from an input/output circuit externally and inputting a signal from outside into the input/output circuit.

The wiring capacitors 320 are wiring capacitors formed in a wiring layer.

The CPU 330 operates by reading code for an application stored in the semiconductor memory device 100, to control the A/D converter 340 and process data outputted from the A/D converter 340.

The A/D converter 340 converts an inputted analog signal to a digital signal and outputs the result.

The RAM 350 is a memory for temporarily holding the output of the A/D converter 340 and for serving as a work area for the CPU 330.

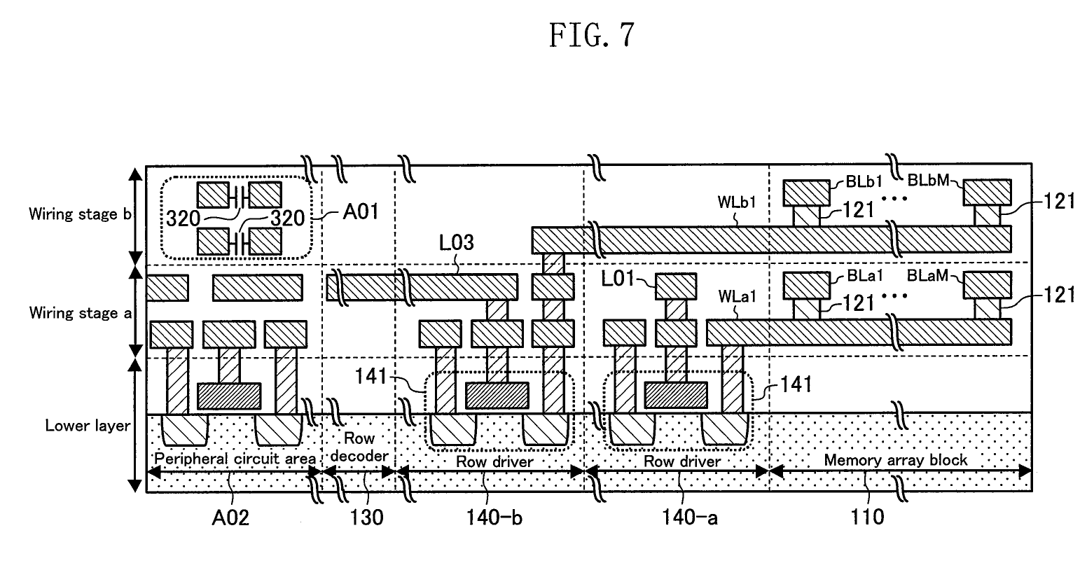

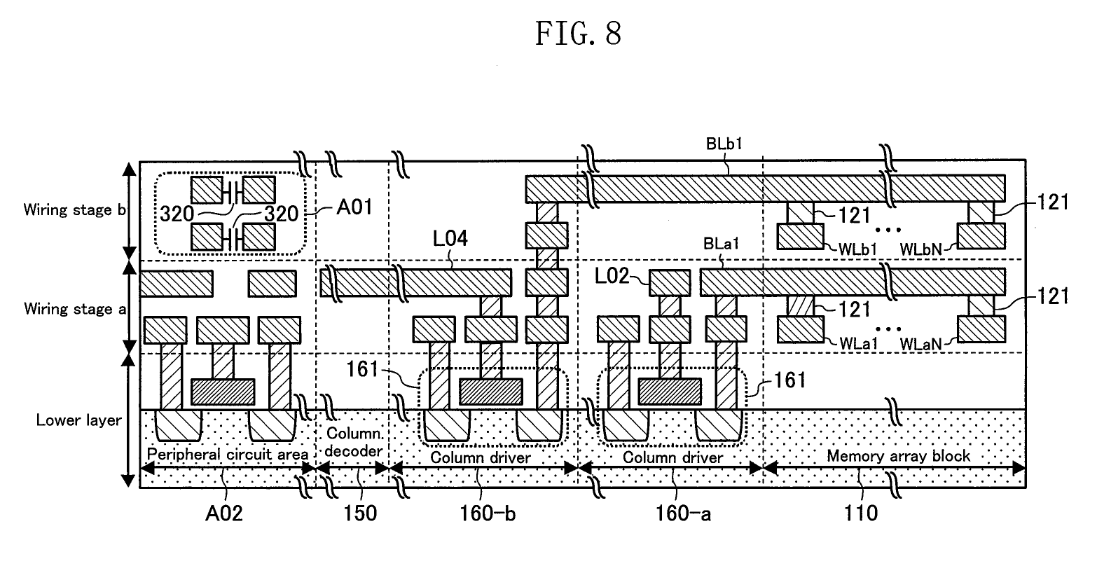

FIG. 7 is a cross-sectional view of the memory-mounted LSI 300 taken along the word line WLa1. FIG. 8 is a cross-sectional view of the memory-mounted LSI 300 taken along the bit line BLa1. In the illustrated example, the memory-mounted LSI 300 has the wiring stage a on the lower layer in which circuit elements are formed and also the wiring stage b formed on the wiring stage a.

As shown in FIGS. 7 and 8, in the lower layer, formed are circuit elements of the row drivers 140-a, b, the row decoder 130, the column decoder 150, the column drivers 160-a, b, the CPU 330, the A/D converter 340 and the RAM 350. That is, in the lower layer of the memory-mounted LSI 300, the placement of the circuit elements is common between the small capacity product type and the maximum capacity product type.

In the wiring stage a, formed are the memory cell array 120 as described above and also interconnects required for the peripheral circuits (such as the drivers, the CPU and the A/D converter) for the memory cell array block 110.

In the wiring stage b, which is made of two wiring layers, another memory cell array 120 is formed as in the wiring stage a. Note that WLb1, . . . , WLbN and BLb1, . . . , BLbM in FIG. 6 and the like respectively denote N (N is a natural number) word lines and M (M is a natural number) bit lines of the memory cell array 120 in the wiring stage b.

In the wiring stage b, the wiring capacitors 320 are formed in a wiring capacitor area A01 (see FIGS. 7 and 8). Although two wiring capacitors 320 are schematically shown in each of FIGS. 7 and 8, the number of necessary wiring capacitors 320 will be discussed later.

In this embodiment, the wiring capacitors 320 are used as smoothing capacitance, which are therefore connected with power supply terminals VSS and VDD. Although the connection of the wiring capacitors 320 with VSS/VDD is not specifically shown in FIGS. 7 and 8, it may be made via a wiring layer underlying the wiring stage b. No extra photomask for the wiring layer or wiring process step is necessary for this connection.

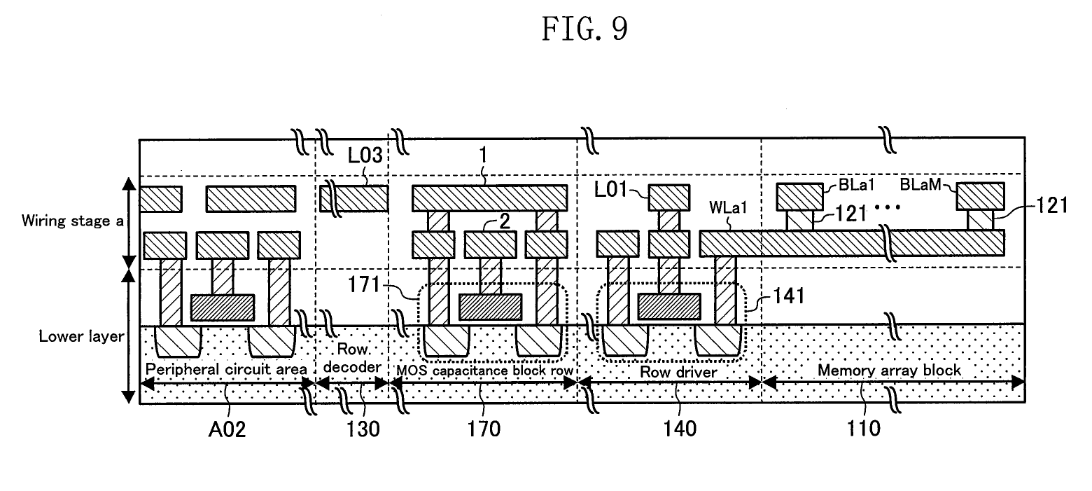

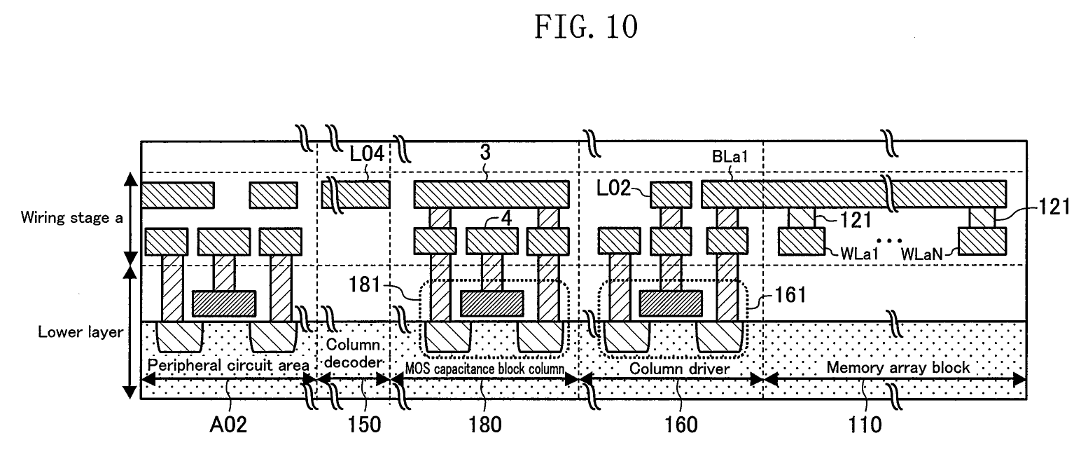

When the maximum capacity product type has two stages of memory cell arrays 120, for example, the driver for one stage will be left unused for a small capacity product type having one stage of memory cell array 120, and this driver can be utilized as MOS capacitors. FIGS. 9 and 10 are cross-sectional views of the memory-mounted LSI 300 in the small capacity product type having one stage of memory cell array 120, taken along the word line WLa1 and the bit line BLa1, respectively.

With increase in the number of stages of memory cell arrays 120, a sufficient number of MOS capacitors may not be secured. In view of this, the memory-mounted LSI 300 may be provided with the wiring capacitors 320 of a number large enough to compensate for short capacitance (smoothing capacitance). In the memory-mounted LSI 300, since the interconnects required for the peripheral circuits are formed only in the wiring stage a as described above, the area of the wiring stage b corresponding to the peripheral circuit area A02 (see FIGS. 7 and 8) is left unused. Hence, in the memory-mounted LSI 300, the unused area is secured as the wiring capacitor area A01 to permit placement of the wiring capacitors 320 therein.

For example, the wiring capacitance value securable when the wiring capacitor area A01 is 0.5 mm² is calculated as follows. Assume that for one wiring layer, the relative dielectric constant of the insulating layer between interconnects=3.7, the thickness of the wiring layer=0.7 μm, the distance between interconnects=0.2 μm, the interconnect width=0.3 μm and the total length of interconnects/mm²=1000 mm. In this case, the wiring capacitance value/mm²=8.85E−12 [F/m]×3.7×0.7E−6 [m]/0.2E−6 [m]×1 [m]=about 115 [pF]. Since the wiring stage b has two wiring layers, the wiring capacitance value=2×115 [pF]=about 230 [pF].

In other words, to secure a capacitance value equivalent to the MOS capacitance value in the example in Embodiment 1, it is only necessary to secure the wiring capacitor area A01 of about 0.65 mm² in the peripheral circuit area A02. This is a sufficiently feasible area.

As described above, in this embodiment, row drivers and column drivers were placed to fit to the maximum capacity product type. Moreover, while the interconnects in the peripheral circuit area common to the product types were formed in the wiring stage available in the small capacity product type, wiring capacitors were provided in a wiring layer left unused. Hence, in expansion of a product to various product types different in the number of stages of memory cell arrays, a given fixed amount of total smoothing capacitance can be secured at any time over the product types in combination of the MOS capacitors and the wiring capacitors.

In other words, in any of the product types, all the characteristics depending on the smoothing capacitance, such as the noise resistance, can be improved. Also, the characteristics depending on the smoothing capacitance can be made uniform over the product types different in memory capacity.

Also, with the common placement of all circuit elements (transistors and the like) in the lower layer among the product types, each product type is only required to design/verify the wiring stage increased. This can suppress the development expense.

With the adoption of the cross-point memory cells, circuits can be placed also under the memory cell array. Hence, even with the placement of peripheral circuits made to fit to the maximum capacity product type as described above, the increase in chip unit price due to increase in chip area can be minimized.

In the memory-mounted LSI 300, the semiconductor memory device 200 may be used in place of the semiconductor memory device 100.

Wiring capacitors may also be provided in a product having only a memory (a product free from the CPU 330 and the like).

### Alteration to Embodiment 3

In the memory-mounted LSI 300, MOS capacitors can be used as the smoothing capacitance for power supply for an input/output circuit, for example. When the maximum voltage of the input/output circuit is higher than a voltage applied to word lines or bit lines, in particular, the thickness of the gate oxide film of the MOS transistors in the MOS transistor blocks may be made the same as the thickness of the gate oxide film of MOS transistors in the input/output circuit.

This is based on the assumption that in some cross-point memories, a voltage higher than the power supply voltage for peripheral circuits around the memory may be applied to the input/output circuit, in consideration of the voltages applied to word lines and bit lines during read and rewrite operation. For example, in dynamic RAMs (DRAMs) and some flash memories as conventional memories, some products achieve high readout speed by applying a voltage higher than the internal power supply voltage used for logic circuits around the memory to word lines.

For example, when the maximum voltage of the input/output circuit is higher than the voltage applied to word lines or bit lines, MOS transistors used as MOS capacitors may be configured to have the same breakdown voltage characteristic as MOS transistors constituting the input/output circuit.

Specifically, the thickness of the gate oxide film of the MOS transistors in the MOS transistor blocks is made the same as the thickness of the gate oxide film of MOS transistors in the input/output circuit, as described above. In general, by giving the same oxide film thickness, MOS transistors same in breakdown voltage characteristic can be formed. Also, the oxide film formation step can be shared, and this presents the merit of suppressing the fabrication cost.

In general, in a product having a large number of terminals, which therefore has a limitation on the chip area due to the pad pitch, sufficient smoothing capacitance for the input/output circuit may fail to be secured. In this embodiment, however, in which the smoothing capacitance for the power supply for the input/output circuit can be secured, the noise resistance of the input/output circuit can be improved.

### Embodiment 4

In Embodiment 4, a fabrication method for the semiconductor memory device and the memory-mounted LSI described above will be described. This fabrication method is applicable to any of the embodiments and alteration described above. Note that the fabrication method exemplified as follows will be for a semiconductor memory device and then a memory-mounted LSI that are to be expanded to two types of products, i.e., a maximum capacity product type having two stages of memory cell arrays and a small capacity product type having one stage of memory cell array.

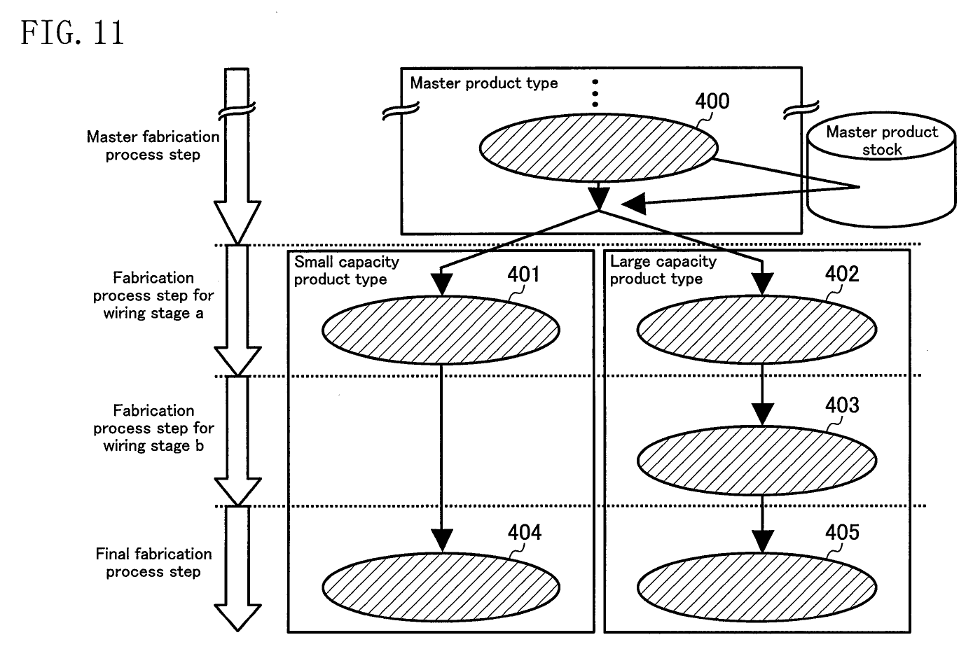

FIG. 11 is a view showing a fabrication method for a semiconductor memory device of an embodiment of the present invention. In FIG. 11, the flow of part of a semiconductor wafer fabrication process related to the present invention is illustrated sequentially from the top downward.

A master fabrication process step is for fabrication of the layer under the wiring stage a (see FIG. 2 and the like, for example) including the diffusion process. In the semiconductor memory device 100 and the memory-mounted LSI 300, the configuration of the circuit elements in the lower layer is common between the small capacity product type and the maximum capacity product type. Hence, in this process step, a common photomask can be used for both product types, and an intermediate product (called a master product type wafer 400) is usable for both the small capacity product type and the maximum capacity product type.

In the next fabrication process step for the wiring stage a, wiring layers including a memory cell array are formed. In this process step, also, wiring is made to produce different product types depending on whether MOS transistors in the MOS transistor blocks are used for drive or used as MOS capacitors. Specifically, for the small capacity product type, wiring is made in the wiring stage a so that MOS transistors in the MOS transistor blocks are used as MOS capacitors, to produce a small capacity product type wafer 401. For the maximum capacity product type, wiring is made in the wiring stage a so that the MOS transistors are used for driving word lines and bit lines, to produce a maximum capacity product type wafer 402. In other words, this and subsequent process steps are different between the small capacity product type and the maximum capacity product type.

In the next fabrication process step for the wiring stage b, for the maximum capacity product type, the wiring stage b including a memory cell array is formed on the maximum capacity product type wafer 402, to produce a maximum capacity product type wafer 403. In this process step, also, wiring capacitors (see FIGS. 7 and 8) are formed as required.

The final fabrication process step is for fabrication of a layer above the wiring stage b. For the small capacity product type, an insulating film or a protection film and the like are formed on the small capacity product type wafer 401, to produce a small capacity product type wafer 404. For the maximum capacity product type, an insulating film or a protection film and the like are formed on the maximum capacity product type wafer 403, to produce a maximum capacity product type wafer 405. In this way, the wafer fabrication is completed.

As described above, in this embodiment, since the circuit configuration in the lower layer is common between the maximum capacity product type and the small capacity product type, the same process can be adopted through the master fabrication process step irrespective of the difference in memory capacity.

That is, by storing master product type wafers in stock in the fabrication process, production adjustment of respective capacity product types is facilitated. Also, since the delivery time can be the lead time of the fabrication process starting from the wiring stage a, delivery can be made in a very short time.

If the maximum capacity product type includes a larger number of stages of memory cell arrays and is expanded to more product types, a wiring stage fabrication process step can be added according to the necessary memory capacity.

### Embodiment 5

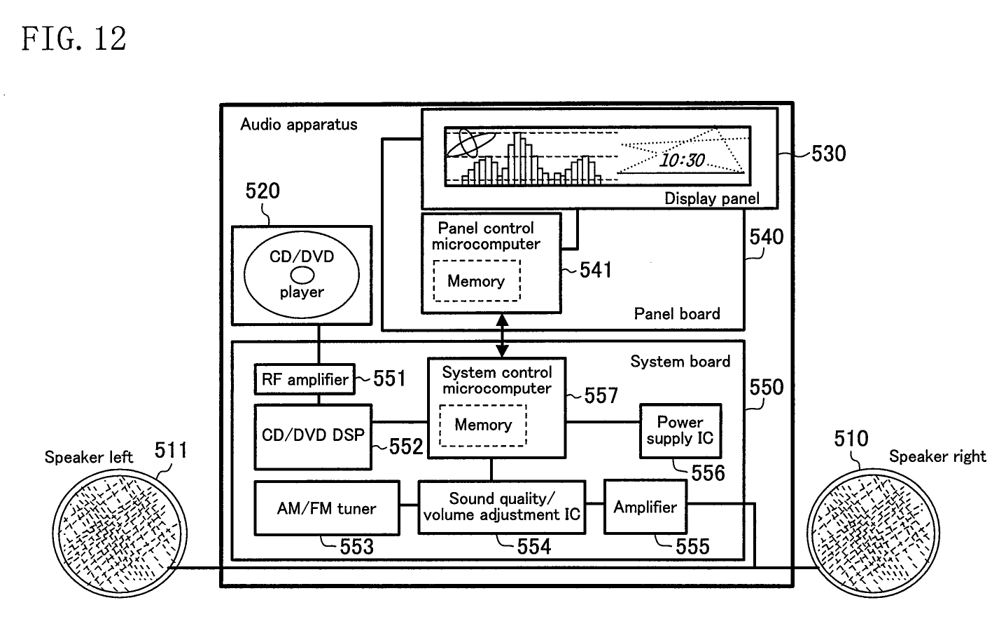

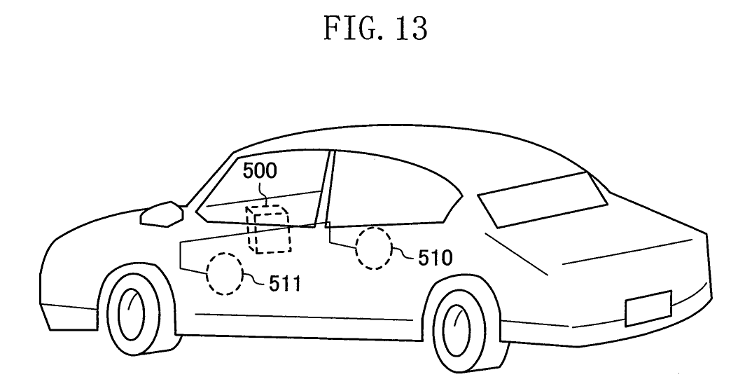

In Embodiment 5, an audio apparatus will be described as an application of the memory-mounted LSI described above. FIG. 12 is a block diagram of an audio apparatus 500 incorporating the memory-mounted LSI 300. FIG. 13 is a general view of an automobile equipped with the audio apparatus 500. As shown in FIG. 13, the automobile is equipped with the audio apparatus 500 and right and left speakers 510 and 511.

(Configuration of Audio Apparatus 500)

As shown in FIG. 12, the audio apparatus 500 includes a CD/DVD player 520, a display panel 530, a panel board 540 and a system board 550.

The CD/DVD player 520 plays back a compact disc (CD) and a digital versatile disc (DVD).

The display panel 530 displays image information such as music information and the time. Specifically, the display panel 530 is a display panel having a liquid crystal display (LCD), an organic electroluminescence (EL) display and the like.

The panel board 540 includes a microcomputer 541 for panel control that drives/controls the LCD and organic EL device of the display panel 530. The panel control microcomputer 541 is made of the memory-mounted LSI 300 incorporating a semiconductor memory device of the present invention (the semiconductor memory device 100, for example). Code for an application is stored in the semiconductor memory device 100 in the panel control microcomputer 541.

The system board 550 is responsible for control of the entire audio system including control of the CD/DVD player 520. The system board 550 includes a RF amplifier 551, a CD/DVD DSP 552, an AM/FM tuner 553, a sound quality/volume adjustment IC 554, an amplifier 555, a power supply IC 556 and a microcomputer 557 for system control.

The RF amplifier 551 amplifies an audio signal outputted from the CD/DVD player 520.

The CD/DVD DSP 552 processes the audio signal from the CD/DVD player 520 inputted via the RF amplifier 551.

The AM/FM tuner 553 receives an AM/FM radio broadcast and outputs an audio signal.

The sound quality/volume adjustment IC 554 performs sound quality/volume processing such as equalization for the audio signal outputted from the AM/FM tuner 553.

The amplifier 555 amplifies the audio signal outputted from the sound quality/volume adjustment IC 554 to drive the right and left speakers 510 and 511.

The power supply IC 556 supplies power to the system control microcomputer 557.

The system control microcomputer 557 controls the CD/DVD DSP 552 and the sound quality/volume adjustment IC 554. Specifically, the system control microcomputer 557 is made of the memory-mounted LSI 300 incorporating a semiconductor memory device of the present invention (the semiconductor memory device 100, for example). Code for an application is stored in the semiconductor memory device 100 in the system control microcomputer (memory-mounted LSI 300).

In the audio apparatus 500, the panel control microcomputer 541 and the system control microcomputer 557 communicate with each other for coordinated operation of conveying information for panel control therebetween.

In this relation, each microcomputer is required to execute high-speed computation in response to the application code written in the semiconductor memory device 110 incorporated therein, and based on this ability, required to secure stable communication. For this reason, in the audio apparatus 500, debugging of a program, for example, is made frequently in some cases. Along with this, the application codes stored in the panel control microcomputer 541 and the system control microcomputer 557 are changed in some cases.

Along with the above change, change may be necessary in the memory capacity of the semiconductor memory device 100. In general, such an apparatus is required to exhibit stable coordinated operation even after the memory capacity incorporated is changed, as well as easiness of development of application code. For this reason, a memory-mounted LSI uniform in specifications and characteristics and good in noise resistance is desired at the time of development of the apparatus.

In particular, in integration of a plurality of LSI products into one chip and in an attempt to reduce application code to resultantly replace an LSI product with a less expensive LSI product smaller in memory capacity, a problem on the compatibility of the memory-mounted LSI with another LSI product may occur due to the difference in memory capacity. Such a problem may be a great impediment to development of audio equipment.

In this embodiment, however, in which the semiconductor memory device of the present invention is used in the panel control microcomputer 541 and the system control microcomputer 557, the characteristics related to the smoothing capacitance can be made uniform. That is, high noise resistance can be secured, and stable coordinated operation can be achieved. Thus, an audio apparatus with high quality and high reliability can be implemented.

Automobiles, among others, have a plurality of grades for the same model in many cases, and also are frequently remodeled for cost reduction. For this reason, in car-mounted audio apparatuses, it is often necessary to have a plurality of types of memory-mounted LSIs different in memory capacity in stock, and replacement of an LSI product with less expensive LSI products smaller in memory capacity is often required. For this reason, the audio apparatus of this embodiment is useful as such a car-mounted audio apparatus.

As described above, the semiconductor memory device, the memory-mounted LSI and the fabrication method for the semiconductor memory device according to the present invention have the effect that the semiconductor memory device can be expanded to a variety of product types different in memory capacity and the characteristics can be made uniform among the product types while increase in chip unit price due to increase in chip area can be prevented. The present invention is therefore useful as a semiconductor memory device having cross-point memory cells, a memory-mounted LSI incorporating such a semiconductor memory device as well as a circuit operating in response to data stored in the semiconductor memory device, and a fabrication method for such a semiconductor memory device.

While the present invention has been described in preferred embodiments, it will be apparent to those skilled in the art that the disclosed invention may be modified in numerous ways and may assume many embodiments other than those specifically set out and described above. Accordingly, it is intended by the appended claims to cover all modifications of the invention which fall within the true spirit and scope of the invention.

What is claimed is:

1. A semiconductor memory device comprising:
a memory cell array block having one or more stages of memory cell arrays stacked one on another, each memory cell array including a plurality of memory cells placed in a matrix at respective intersections of a plurality of word lines and a plurality of bit lines; and
a plurality of MOS transistor blocks same in the configuration of circuit elements, MOS transistors being included as one kind of the circuit elements,
wherein in part of the plurality of MOS transistor blocks, the MOS transistors are used for drive of the plurality of word lines or the plurality of bit lines, and in at least part of the remaining MOS transistor blocks, the MOS transistors are used as MOS capacitors.

2. The device of claim 1, further comprising wiring capacitors of a number corresponding to the number of stages of the memory cell arrays.

3. The device of claim 1, wherein a guard band is placed between a well for MOS transistors used for drive of the plurality of word lines or the plurality of bit lines and a well for MOS transistors used as MOS capacitors.

4. The device of claim 1, further comprising an input/output circuit having MOS transistors and connected with external terminals,
wherein the MOS transistors of the input/output circuit are the same in gate oxide film thickness as the MOS transistors in the MOS transistor blocks, and
the MOS capacitors are connected with power supply for the input/output circuit

5. The device of claim 1, wherein the memory cells are memory cells using ferromagnetic tunneling magneto-resistance.

6. The device of claim 1, wherein the memory cells are resistive memory cells that store data with resistance change.

7. The device of claim 1, wherein the memory cells are memory cells using an antifuse.

8. The device of claim 1, wherein predetermined voltages are supplied to the terminals of each of the MOS transistors used as MOS capacitors via a wiring layer.

9. A fabrication method for a semiconductor memory device including a memory cell array block having one or more stages of memory cell arrays stacked one on another, each memory cell array including a plurality of memory cells placed in a matrix at respective intersections of a plurality of word lines and a plurality of bit lines, the semiconductor memory device being expanded to product types different in capacity depending on the number of stages of memory cell arrays, the method comprising:
a lower layer formation step of forming a plurality of MOS transistor blocks same in the configuration of circuit elements and including MOS transistors as one kind of the circuit elements in a lower layer;
a wiring layer formation step of executing a first sub-step of wiring the terminals of each of the MOS transistors in a wiring layer so that all of the plurality of MOS transistor blocks drive the plurality of word lines or the plurality of bit lines in fabrication of a product type maximum in capacity among the product types, and executing a second sub-step of wiring the terminals of each of the MOS transistors in the wiring layer so that the MOS transistors drive the plurality of word lines or the plurality of bit lines in part of the plurality of MOS transistor blocks and wiring the terminals of each of the MOS transistors in the wiring layer so that the MOS transistors function as MOS capacitors in at least part of the remaining MOS transistor blocks in fabrication of a product type other than the product type maximum in capacity among the product types; and
a memory cell array addition step of, in the case of requiring an additional memory cell array, stacking a desired number of additional wiring layers including the memory cell array on the wiring layer.

10. The method of claim 9, wherein the wiring layer formation step further includes forming wiring capacitors of a number based on the number of stages of memory cell arrays.

11. A memory-mounted LSI comprising:
the semiconductor memory device of claim 1; and
a circuit operating in response to data stored in the semiconductor memory device.

12. An audio apparatus incorporating the semiconductor memory device of claim 1.

13. An automobile incorporating the audio apparatus of claim 12.

14. A semiconductor memory device comprising a memory cell array block having one or more stages of memory cell arrays stacked one on another, each memory cell array including a plurality of memory cells placed in a matrix at respective intersections of a plurality of word lines and a plurality of bit lines, the semiconductor memory device being expanded to product types different in capacity depending on the number of stages of memory cell arrays,
wherein the semiconductor memory device further comprises a plurality of MOS transistor blocks same in the configuration of circuit elements and including MOS transistors as one kind of the circuit elements,
for a product type maximum in capacity among the product types, all of the plurality of MOS transistor blocks are used for drive of the plurality of word lines or the plurality of bit lines, and
for a product type other than the product type maximum in capacity among the product types, the MOS transistors are used for drive of the plurality of word lines or the plurality of bit lines in part of the plurality of MOS transistor blocks while the MOS transistors are used as MOS capacitors in at least part of the remaining MOS transistor blocks.
